(19) United States
(12) Patent Application Publication
(10) Pub. No.: US 2026/0260818 A1
(43) Pub. Date: Sep. 3, 2026

(54) MULTILAYER ELECTRONIC COMPONENT AND MOUNTING BOARD THEREOF

(71) Applicant: SAMSUNG ELECTRO-MECHANICS CO., LTD., Suwon-si (KR)

(72) Inventor: Se Hun PARK, Suwon-si (KR)

(73) Assignee: SAMSUNG ELECTRO-MECHANICS CO., LTD., Suwon-si (KR)

(21) Appl. No.: 19/421,460

(22) Filed: Dec. 16, 2025

(30) Foreign Application Priority Data
Feb. 28, 2025 (KR) 10-2025-0026991

(51) Int. Cl. H01G 4/248; H01G 2/06; H01G 4/30

(52) U.S. Cl. CPC H01G 4/248; H01G 2/065; H01G 4/30

(57) ABSTRACT

A multilayer electronic component includes a body including a dielectric layer and internal electrodes disposed alternately with the dielectric layer, first and second surfaces opposing each other in a thickness direction, third and fourth surfaces opposing each other in a length direction, and fifth and sixth surfaces opposing each other in a width direction, an external electrode disposed on the third or fourth surface and extending to a portion of the first and second surfaces, and a metal terminal disposed on the first or second surface and connected to the external electrode, a recess portion is disposed on an external side surface of the metal terminal in the length direction, and an upper hole and a lower hole are disposed on the upper and lower surfaces of the metal terminal, respectively, and the upper hole may not overlap the lower hole in the thickness direction.

### CROSS-REFERENCE TO RELATED APPLICATION(S)

This application claims benefit of priority to Korean Patent Application No. 10-2025-0026991 filed on Feb. 28, 2025 in the Korean Intellectual Property Office, the disclosure of which is incorporated herein by reference in its entirety.

### TECHNICAL FIELD

The present disclosure relates to a multilayer electronic component and a mounting board thereof.

Multilayer ceramic capacitors (MLCCs), a type of multilayer electronic component, are chip-shaped capacitors that are mounted on the printed circuit boards of various electronic products such as video display devices, including Liquid Crystal Displays (LCDs) and Plasma Display Panels (PDPs), computers, smartphones, and mobile phones to charge or discharge electricity therein or therefrom. MLCCs are used as components of various electronic devices due to their advantages of being small, having high capacity, and being easy to mount.

Since a dielectric layer of the MLCC has piezoelectricity, it may have a characteristic of vibrating when voltage is applied to the MLCC. These vibrations are transmitted to the printed circuit board through a solder, causing a vibration sound. The vibration sound may correspond to an audible frequency that is unpleasant to humans, and is known as acoustic noise. In addition, regardless of a user's awareness, if the piezoelectric vibration of MLCC occurs in the high-frequency range of 20 kHz or higher, it may cause malfunctions in various sensors used in the IT and electrical industries.

To reduce acoustic noise, conventional methods have been proposed, such as installing bumps on external electrodes or installing interposers between MLCCs and printed circuit boards. However, if bumps are installed on external electrodes, there is a risk that a bending strength of the MLCC will decrease, and a bonding strength between the external electrodes and bumps must be additionally considered.

### SUMMARY

An aspect of the present disclosure aspect of the present disclosure is to provide a multilayer electronic component having excellent bending strength while reducing acoustic noise.

Another aspect of the present disclosure is to provide a multilayer electronic component having improved bonding strength between an external electrode and a metal terminal.

However, the aspects of the present disclosure are not limited to those set forth herein, and will be more easily understood in the course of describing specific example embodiments of the present disclosure.

According to an aspect of the present disclosure, a multilayer electronic component may include a body including a dielectric layer and internal electrodes disposed alternately with the dielectric layer, first and second surfaces and opposing each other in a thickness direction, third and fourth surfaces connected to the first and second surfaces and opposing each other in a length direction, and fifth and sixth surfaces connected to the first to fourth surfaces and opposing each other in a width direction, an external electrode disposed on the third or fourth surface and extending to a portion of the first and second surfaces, and a metal terminal disposed on the first or second surface and connected to the external electrode. A recess portion may be disposed on the external side surface of the metal terminal in the length direction, an upper hole and a lower hole may be disposed on the upper surface and the lower surface of the metal terminal, respectively, in the thickness direction, and the upper hole may not overlap the lower hole in the thickness direction.

As one of the many effects of the present disclosure, a multilayer electronic component having excellent bending strength while reducing acoustic noise may be provided.

As one of the effects of the present disclosure, a multilayer electronic component may be provided with improved bonding strength between an external electrode and a metal terminal.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view schematically illustrating a multilayer electronic component according to an embodiment of the present disclosure;

FIG. 2 is an exploded perspective view schematically illustrating a multilayer electronic component according to an embodiment of the present disclosure;

FIG. 3 is a cross-sectional view schematically illustrating a cross-section of the body and external electrode;

FIG. 4 is a schematic cross-sectional view taken along line I-I′ of FIG. 1;

FIG. 5 is a schematic cross-sectional view taken along line II-II′ of FIG. 1;

FIG. 6 is a cross-sectional view schematically illustrating a form in which the multilayer electronic component illustrating in FIG. 5 is mounted on a printed circuit board;

FIG. 7A and FIG. 7B are plan views of a first metal terminal and a second metal terminal of FIG. 1;

FIGS. 8A, 8B, 9A, 9B, 10A, 10B, 11A, 11B, 12A and 12B are plan views of a first metal terminal and a second metal terminal of other embodiments of the present disclosure, corresponding to FIG. 7;

FIG. 13 is a graph measuring a bonding strength of comparative examples, examples 1 and 2;

FIG. 14 is a perspective view schematically illustrating a multilayer electronic component according to another embodiment of the present disclosure;

FIG. 15 is a schematic cross-sectional view taken along line III-III′ cross-section of FIG. 14;

FIGS. 16A and 16B are plan views of a first metal terminal and a second metal terminal of FIG. 14;

FIGS. 17A, 17B, 18A, 18B, 19A and 19B are plan views of a first metal terminal and a second metal terminal of other embodiments of the present disclosure, corresponding to FIG. 16.

### DETAILED DESCRIPTION

Hereinafter, embodiments of the present disclosure will be described with reference to detailed embodiments and accompanying drawings. However, the embodiments of the present disclosure may be modified in many different forms, and the scope of the present disclosure is not limited to the embodiments described below. In addition, the embodiments of the present disclosure are provided to more completely describe the present disclosure to those skilled in the art. Therefore, the shape and size of elements in the drawings may be exaggerated for clearer explanation, and elements indicated by the same reference numerals in the drawings are the same elements.

In addition, to clearly describe the present disclosure in the drawings, parts irrelevant to the description are omitted, and the size and thickness of each component illustrated in the drawings are arbitrarily illustrated for convenience of description, and thus, the present disclosure is not necessarily limited to the illustrated embodiment. Also, components having the same function within the scope of the same concept are described using the same reference numerals. Furthermore, throughout the specification, when a certain component is said to “include,” it means that it may further include other components without excluding other components unless otherwise stated.

In the drawing, the X-direction may be defined as the thickness (T) direction, the Y-direction as the length (L) direction, and the Z-direction as the width (W) direction.

### 1. First Example

### Multilayer Electronic Component

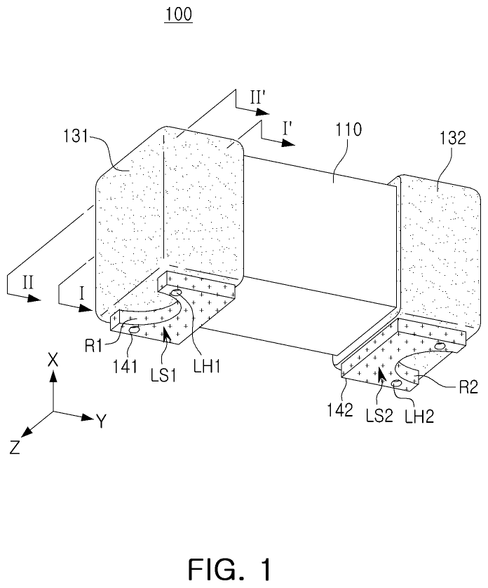

FIG. 1 is a perspective view schematically illustrating a multilayer electronic component according to an embodiment of the present disclosure.

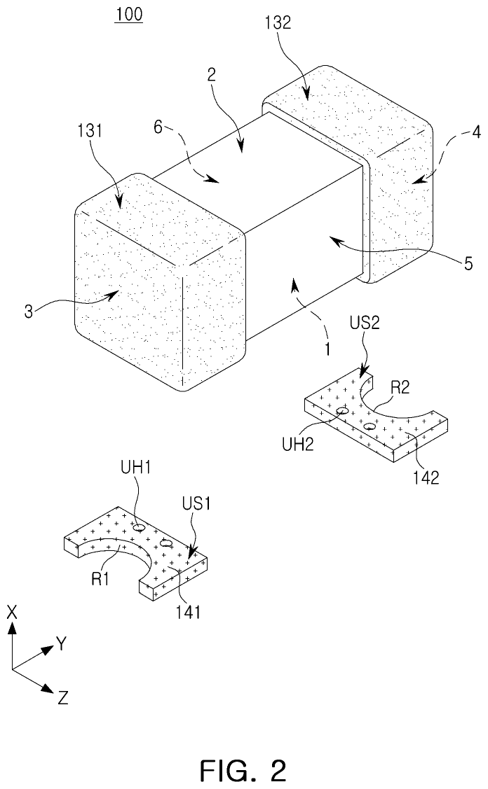

FIG. 2 is an exploded perspective view schematically illustrating a multilayer electronic component according to an embodiment of the present disclosure.

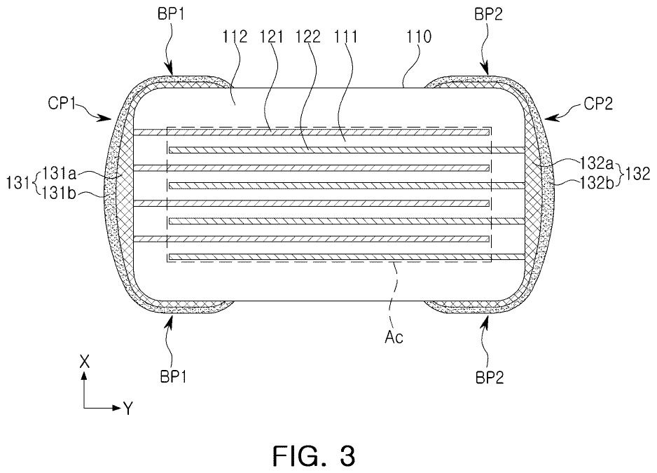

FIG. 3 is a schematic cross-sectional view illustrating a cross-section of the body and external electrode.

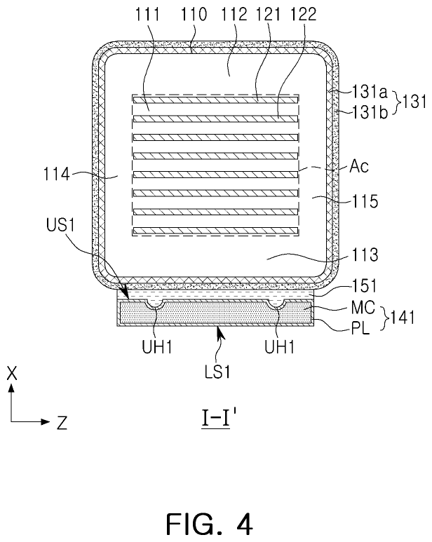

FIG. 4 is a schematic cross-sectional view taken along line I-I′ cross-section of FIG. 1.

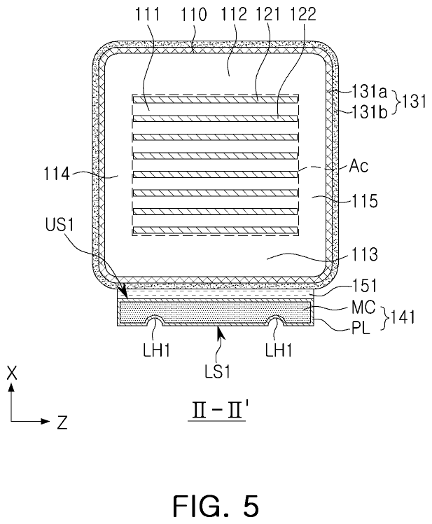

FIG. 5 is a schematic cross-sectional view taken along line II-II′ cross-section of FIG. 1.

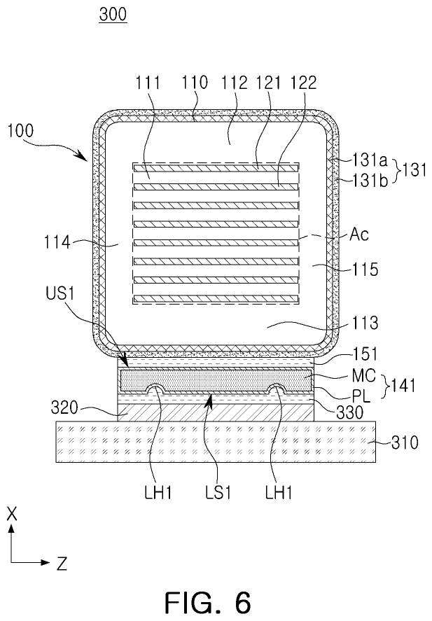

FIG. 6 is a cross-sectional view schematically illustrating a form in which the multilayer electronic component illustrating in FIG. 5 is mounted on a printed circuit board.

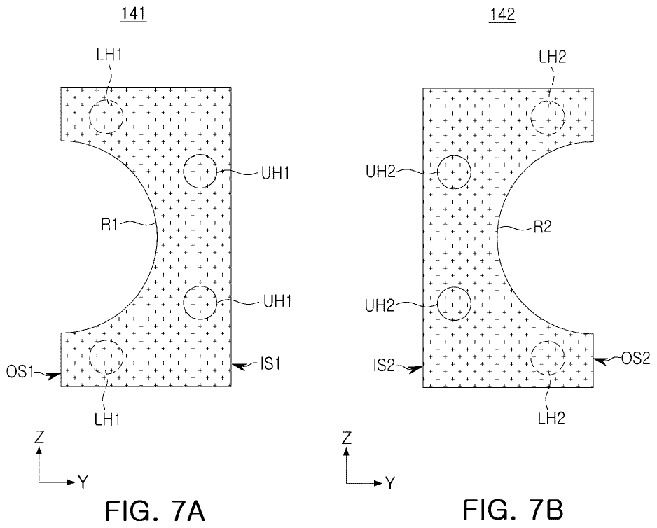

FIGS. 7A and 7B are plan views of the first metal terminal and the second metal terminal of FIG. 1.

Hereinafter, a multilayer electronic component 100 according to an embodiment will be described in detail with reference to FIGS. 1 through 7B. Furthermore, while a multilayer ceramic capacitor is described as an example of a multilayer electronic component, the present disclosure is not limited thereto and may be applied to various multilayer electronic components, such as inductors, piezoelectric elements, varistors, or thermistors.

A length of the multilayer electronic component 100 may be greater than a width and thickness of the multilayer electronic component 100, but the present disclosure is not limited thereto. For example, the length of the multilayer electronic component 100 may be smaller than the width of the multilayer electronic component 100. The width of the multilayer electronic component 100 may be smaller or greater than the thickness of the multilayer electronic component 100, and may vary depending on the specifications or characteristics of the multilayer electronic component 100.

The multilayer electronic component 100 may include a body 110, external electrodes 131 and 132, and metal terminals 141 and 142.

While there are no specific limitations on the detailed shape of the body 110, as illustrated, the body 110 may be formed in a hexahedral shape or a similar shape. Due to shrinkage of the ceramic powder contained in the body 110 during a sintering process or due to a polishing process on the edges of the body 110, the body 110 may not be a perfectly straight hexahedral shape, but may have a substantially hexahedral shape.

The body 110 may have first and second surfaces 1 and 2 opposing each other in the thickness direction, third and fourth surfaces 3 and 4 connected to the first and second surfaces 1 and 2 and opposing each other in the length direction, and fifth and sixth surfaces 5 and 6 connected to the first to fourth surfaces 1, 2, 3 and 4 and opposing each other in the width direction.

The body 110 may include a dielectric layer 111 and internal electrodes 121 and 122 disposed alternately with the dielectric layer 111. A plurality of dielectric layers 111 forming the body 110 are in a sintered state, and the boundaries between adjacent dielectric layers 111 may be so integrated that they are difficult to discern without a scanning electron microscope (SEM).

The dielectric layer 111 may, for example, include a perovskite-type compound represented by ABO₃ as the main component thereof. The perovskite compound represented by ABO₃ may include at least one, for example, BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃ and (Ca₁₋ₓSrₓ)(Zr_{1-y}Ti_{y})O₃ (0<x≤0.5, 0<y≤0.5).

An average thickness of the dielectric layer 111 may be, for example, 0.1 μm to 20 μm, 0.1 μm to 10 μm, 0.1 μm to 5 μm, 0.1 μm to 2 μm, or 0.1 μm to 0.4 μm.

The body 110 may include a capacitance formation portion Ac forming a capacitance by including a first internal electrode 121 and a second internal electrode 122 disposed alternately with a dielectric layer 111 therebetween. A stacking direction of the internal electrodes 121 and 122 may be in the thickness direction or the width direction. In this disclosure, an embodiment in which the stacking direction of the internal electrodes 121 and 122 is in the thickness direction is described.

The first internal electrode 121 is spaced apart from a fourth surface 4 and may be connected to a first external electrode 131 on a third surface 3. The second internal electrode 122 is spaced apart from the third surface 3 and may be connected to a second external electrode 132 on the fourth surface 4.

A conductive metal included in the internal electrodes 121 and 122 may be one or more of Ni, Cu, Pd, Ag, Au, Pt, Sn, W, Ti, and alloys thereof, and more preferably may include Ni, but the present disclosure is not limited thereto.

An average thickness of the internal electrodes 121 and 122 may be, for example, 0.1 μm to 3.0 μm, 0.1 μm to 1.0 μm, or 0.1 μm to 0.4 μm.

The average thickness of the dielectric layer 111 and the average thickness of the internal electrodes 121 and 122 may be measured by scanning the length and thickness-direction cross-sections (hereinafter referred to as L-T cross-sections) of the multilayer electronic component 100 using a scanning electron microscope (SEM) at 10,000× magnification. In more detail, the average thickness of the dielectric layer 111 may be measured by measuring the thickness at multiple points on a single dielectric layer 111, for example, five equally spaced points in the length direction, and then taking the average value. Additionally, the average thickness of the internal electrodes 121 and 122 may be measured by measuring the thickness at multiple points on a single internal electrode 121 or 122, for example, at five equally spaced points in the length direction, and then taking the average value. The five equally spaced points may be designated in the capacitance formation portion Ac. By performing the measurement of these average values for each of the ten dielectric layers 111 and ten internal electrodes 121 and 122, and then taking the average values, the average thickness of the dielectric layer 111 and the average thickness of the internal electrodes 121 and 122 may be more generalized.

The body 110 may include cover portions 112 and 113 disposed on both surfaces of the capacitance formation portion Ac opposing each other in the thickness direction, and the margin portions 114 and 115 disposed on both surfaces of the capacitance formation portion Ac opposing each other in the width direction. The cover portions 112 and 113, and the margin portions 114 and 115 may have a similar configuration to the dielectric layer 111 except that they do not include internal electrodes.

An average thickness of the cover portions 112 and 113 may be, for example, 150 μm or less, 100 μm or less, 30 μm or less, or 20 μm or less. The average thickness of the cover portions 112 and 113 may be, for example, 5 μm or more, 10 μm or more, or 30 μm or more. Here, the average thickness tc of the cover portions 112 and 113 may mean the average thickness of each of a first cover portion 112 and a second cover portion 113. The average thickness tc of the cover portions 112 and 113 may be an average value of the thickness measured at five equally spaced points on the L-T cross-section of the multilayer electronic component 100.

An average width of the margin portions 114 and 115 may be, for example, 150 μm or less, 100 μm or less, 20 μm or less, or 15 μm or less. The average width of the margin portions 114 and 115 may be, for example, 5 μm or more, 10 μm or more, or 30 μm or more. Here, the average width of the margin portions 114 and 115 may mean the average width of each of the first margin portion 114 and the second margin portion 115. The average width of the margin portions 114 and 115 may be the average of the widths measured at five equally spaced points on the cross-section (W-T cross-section) of the multilayer electronic component 100 in the width direction and thickness direction.

The external electrodes 131 and 132 may be disposed on the third or fourth surface 3 or 4, and may extend to a portion of the first and second surfaces 1 and 2. The external electrode 131 and 132 may include, for example, a first external electrode 131 disposed on the third surface 3 and extending on a portion of the first, second, fifth, and sixth surfaces 1, 2, 5 and 6, and a second external electrode 132 disposed on the fourth surface 4 and extending on a portion of the first, second, fifth, and sixth surfaces 1, 2, 5 and 6.

A region disposed on the third surface 3 of the first external electrode 131 may be defined as a first connection portion CP1, and the region extended from the first connection portion CP1 and disposed on the first and second surfaces 1 and 2, may be defined as a first band portion BP1. The region disposed on the fourth surface 4 of the second external electrode 132 may be defined as a second connection portion CP2, and the region extended from the second connection portion CP2 and disposed on the first and second surfaces 1 and 2 may be defined as the second band portion BP2.

The type or shape of the external electrodes 131 and 132, is not particularly limited, and may have a multilayer structure. For example, the external electrodes 131 and 132 may include the base electrode layers 131a and 132a in contact with the internal electrodes 121 and 122, and the metal layers 131b and 132b disposed on the base electrode layers 131a and 132a.

The base electrode layers 131a and 132a may include a sintered electrode layer including metal and glass. The metal included in the sintered electrode layer may include, for example, Cu, Ni, Pd, Pt, Au, Ag, Pb and/or an alloy including the same. The glass included in the sintered electrode layer may include, for example, one or more oxides of Ba, Ca, Zn, Al, B, and Si.

Meanwhile, the base electrode layers 131a and 132a may be configured of only a sintered electrode layer, but the present disclosure is not limited thereto, and the base electrode layers 131a and 132a may include a sintered electrode layer including metal and glass, and a resin electrode layer disposed on the sintered electrode layer and including metal particles and resin.

The metal particles included in the resin electrode layer may include at least one of spherical particles and flake-shaped particles. The metal particles included in the resin electrode layer may include, for example, Cu, Ni, Pd, Pt, Au, Ag, Pb, Sn and/or an alloy including the same. The resin included in the resin electrode layer may include, for example, one or more of epoxy resin, acrylic resin, and ethyl cellulose.

The metal layers 131b and 132b may include, for example, Ni, Sn, Pd and/or an alloy including the same, and may be formed of multiple layers. The metal layers 131b and 132b may be, for example, a Ni plating layer or a Sn plating layer, and may be formed in a form in which the Ni plating layer and the Sn plating layer are formed sequentially. The metal layers 131b and 132b may include multiple Ni plating layers and/or multiple Sn plating layers.

Although the drawing describes a structure in which a multilayer electronic component 100 has two external electrodes 131 and 132, it is not limited thereto, and the number or shape of the external electrodes 131 and 132 may be changed depending on the shape of the internal electrodes 121 and 122, or other purposes.

The metal terminals 141 and 142 may be disposed on the first or second surface 1 or 2, and connected to the external electrodes 131 and 132. The first metal terminal 141 may be disposed on the first or second surface 1 or 2 and connected to the first external electrode 131, and the second metal terminal 142 may be disposed on the first or second surface 1 or 2 and connected to the second external electrode 132. Specifically, the metal terminals 141 and 142 may be connected to the band portions BP1 and BP2.

Referring to FIGS. 4 and 5, a first conductive adhesive 151 may be disposed between the first external electrode 131 and the first metal terminal 141. A second conductive adhesive (not illustrated) may be disposed between the second external electrode 132 and the second metal terminal 142. The first conductive adhesive 151 may be, for example, solder or a conductive epoxy resin.

The metal terminals 141 and 142 may basically contribute to prevent piezoelectric vibrations generated in the body 110 from being transmitted to the printed circuit board by sufficiently spacing out distance between the body 110 and the printed circuit board. The material of the metal terminals 141 and 142 may be a metal component, and since the metal component has better ductility than the ceramic component, the piezoelectric vibration generated in the body 110 may be effectively absorbed, thereby reducing the acoustic noise of the multilayer electronic component 100.

A recessed portions R1 and R2 may be disposed in the metal terminals 141 and 142. A first recessed portion R1 may be disposed in the first metal terminal 141, and a second recessed portion R2 may be disposed in the second metal terminal 142. Referring to FIGS. 7A and 7B, the recessed portions R1 and R2 may be disposed on the external side surfaces OS1 and OS2 of the metal terminals 141 and 142 in the length direction.

Referring to FIGS. 7A and 7B, the recessed portions R1 and R2 may have a concave shape toward the internal side surfaces IS1 and IS2 of the metal terminals 141 and 142 in the length direction. However, the present disclosure is not limited thereto, and the cross-sections (L-W cross sections) of the recessed portions R1 and R2 in the length direction and width direction, may have a square shape.

When the multilayer electronic component 100 is mounted on the printed circuit board using a conductive mounting agent, the recessed portions R1 and R2 may serve as solder pockets by providing a space in which the molten conductive mounting agent can be filled. This allows the conductive material to lower the height of the solder fillet rising in the thickness direction by climbing the external electrodes 131 and 132, this blocks the transmission path of piezoelectric vibration generated in the body 110, thereby reducing acoustic noise of the multilayer electronic component 100.

Referring to FIG. 2, upper holes UH1 and UH2 may be disposed on the upper surfaces US1 and US2 of the metal terminals 141 and 142. Referring to FIG. 1, lower holes LH1 and LH2 may be disposed on the lower surfaces LS1 and LS2 of the metal terminals 141 and 142. The first metal terminal 141 may include a first upper hole UH1 and a first lower hole LH1 disposed on the upper surface US1 and the lower surface LS1, respectively, and the second metal terminal 142 may include a second upper hole UH2 and a second lower hole LH2 disposed on the upper surface US2 and the lower surface LS2, respectively. The upper holes UH1 and UH2, and the lower holes LH1 and LH2 have a shape that does not completely penetrate the metal terminals 141 and 142, and may have, for example, a blind hole shape.

The metal terminals 141 and 142 include upper holes UH1 and UH2, and lower holes LH1 and LH2, thereby reducing the stiffness of the metal terminals 141 and 142, thereby improving the bending strength of the multilayer electronic component 100.

In addition, the upper holes UH1 and UH2 may increase the contact area between the metal terminals 141 and 142, and the conductive adhesive, thereby improving the bonding strength between the external electrodes 131 and 132, and the metal terminals 141 and 142. For example, referring to FIG. 4, the first conductive adhesive 151 may fill at least a portion of the first upper hole UH1.

The lower holes LH1 and LH2 may increase the contact area between the metal terminals 141 and 142 and a conductive material 330, thereby improving the bonding strength between the metal terminals 141 and 142, and the printed circuit board.

According to an embodiment of the present disclosure, the upper holes UH1 and UH2 may not overlap the lower holes LH1 and LH2 along the thickness direction. Specifically, the first upper hole UH1 may not overlap the first lower hole LH1 along the thickness direction, and the second upper hole UH2 may not overlap the second lower hole LH2 along the thickness direction. This allows each upper holes UH1 and UH2 and lower holes LH1 and LH2 to have sufficient depth, and sufficiently increases the contact area between the metal terminals 141 and 142, and the conductive bonding agent and the contact area between the metal terminals 141 and 142, and the conductive mounting agent.

In an embodiment, the upper holes UH1 and UH2, and the lower holes LH1 and LH2 may be disposed in multiple, respectively, and the plurality of upper holes UH1 and UH2 may not overlap the plurality of lower holes LH1 and LH2 along the thickness direction. The number of upper holes UH1 and UH2, and lower holes LH1 and LH2 is not particularly limited, and may be 2 or more, 3 or more, 4 or more, or 5 or more, respectively. Since each of the plurality of upper holes UH1 and UH2 does not overlap the plurality of lower holes LH1 and LH2 along the thickness direction, the bending strength improvement and bonding strength improvement effects of the present disclosure may be further enhanced.

Referring to FIGS. 4 to 6, the first metal terminal 141 may include a first metal core MC and a first plating layer PL disposed on the first metal core MC. Similarly, the second metal terminal 142 may include a second metal core (not illustrated) and a second plating layer (not illustrated) disposed on the second metal core. The first plating layer PL may be disposed to cover, for example, the external side surface of the first metal core MC, and the first plating layer PL may extend into the internal of the first upper hole UH1 and the first lower hole LH1. The first plating layer PL may extend into each of the plurality of first upper hole UH1 and each of the plurality of first lower hole LH1. This allows the first conductive adhesive 151 to sufficiently flow into the internal of the first upper hole UH1 through the first plating layer PL.

The metal core MC may include, for example, one or more of Cu, Ni, Ag, Sn, Pt, Pd, Fe, Al, and alloys thereof, phosphor bronze, and stainless steel. The plating layer PL may include, for example, one or more of Ni, Sn and Au. The plating layer PL may be formed of plurality of layers and may include sequentially laminated Ni plating layers and Sn plating layers.

### Mounting Board of Multilayer Electronic Component

Hereinafter, with reference to FIG. 6, a mounting substrate 300 of a multilayer electronic component according to an embodiment of the present disclosure will be described. Redundant descriptions of the configuration of the aforementioned multilayer electronic component 100 will be omitted.

Referring to FIG. 6, a mounting substrate 300 of the multilayer electronic component may include a printed circuit board 310 including electrode pads 320. The printed circuit board 310 may include, for example, a resin such as glass epoxy or a ceramic such as glass ceramic. The printed circuit board 310 may have, for example, a form in which multiple insulating layers are laminated. The printed circuit board 310 may include a first electrode pad 320 connected to the first external electrode 131 and a second electrode pad (not illustrated) connected to the second external electrode.

The mounting substrate 300 of the multilayer electronic component may include a conductive material 330 disposed between the electrode pad 320 and the metal terminal 141. The conductive material 330 may be, for example, a solder for bonding, and may include at least one of tin (Sn), antimony (Sb), cadmium (Cd), lead (Pb), zinc (Zn), aluminum (Al), and copper (Cu), but the present disclosure is not limited thereto.

According to an embodiment, the conductive material 330 may fill at least a portion of a lower hole LH1 disposed on the lower surface LS1 of the metal terminal 141. This may improve the bonding strength between the metal terminal 141 and the printed circuit board, and may provide the mounting substrate 300 of the multilayer electronic component on which the multilayer electronic component 100 is stably mounted.

### Various Variations of Metal Terminals

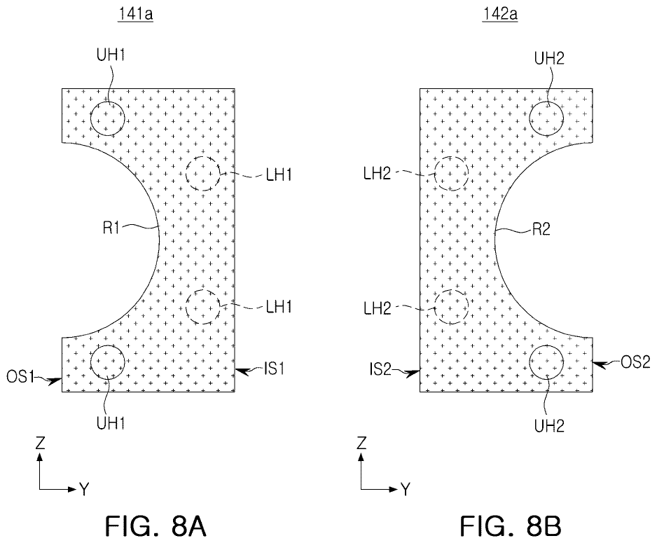

FIGS. 8A, 8B, 9A, 9B, 10A, 10B, 11A, 11B, 12A and 12B are plan views of a first metal terminal and a second metal terminal of other embodiments of the present disclosure, corresponding to FIG. 7. Hereinafter, various modified examples of the metal terminal will be described with reference to FIGS. 7A to 12B. Each variation is described separately, but overlapping explanations are omitted.

Referring to FIGS. 7A and 7B, the plurality of upper holes UH1 and UH2 may be disposed closer to the internal side surfaces IS1 and IS2 of the metal terminals 141 and 142 in the length direction than the plurality of lower holes LH1 and LH2. The plurality of upper holes UH1 and UH2 may be disposed closer to the center portion of the metal terminals 141 and 142 in the width direction than the plurality of lower holes LH1 and HL2. The plurality of upper holes UH1 and UH2 may be spaced apart from each other in the width direction, and the plurality of lower holes LH1 and LH2 may be spaced apart from each other in the width direction. The distance between the plurality of upper holes UH1 and UH2 in the width direction may be shorter than the distance between the plurality of lower holes LH1 and LH2 in the width direction.

Referring to FIGS. 8A and 8B, the plurality of upper holes UH1 and UH2, and lower holes LH1 and LH2 may be disposed in each of the metal terminals 141a and 142a. The plurality of lower holes LH1 and LH2 may be disposed closer to the internal side surfaces IS1 and IS2 of the metal terminals 141a and 142a in the length direction than the plurality of upper holes UH1 and UH2. The plurality of lower holes LH1 and LH2 may be disposed closer to the center of the metal terminals 141a and 142a in the width direction than the plurality of upper holes UH1 and UH2. The plurality of upper holes UH1 and UH2 may be spaced apart from each other in the width direction, and the plurality of lower holes LH1 and LH2 may be spaced apart from each other in the width direction. The distance between the plurality of lower holes LH1 and LH2 in the width direction may be shorter than the distance between the plurality of upper holes UH1 and UH2 in the width direction. That is, the metal terminals 141a and 142a illustrated in FIGS. 8A and 8B may have positions of the upper portion and lower holes opposite to those of the metal terminals 141 and 142 illustrated in FIGS. 7A and 7B.

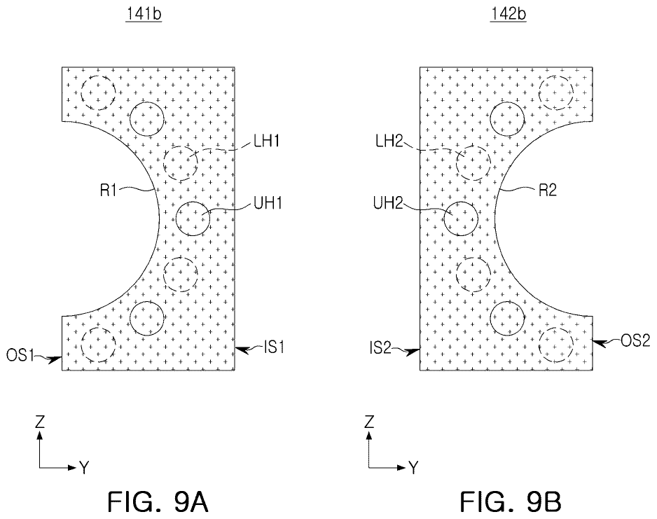

Referring to FIGS. 9A and 9B, the plurality of upper holes UH1 and UH2, and lower holes LH1 and LH2 may be disposed in each of the metal terminals 141b and 142b. In an embodiment, the upper holes UH1 and UH2, and the lower holes LH1 and LH2 may be disposed alternately along the periphery of the recessed portions R1 and R2 when viewed in the thickness direction.

In FIGS. 7A to 9B, the cross sections of the upper holes UH1 and UH2, and the lower holes LH1 and LH2 may be circular or elliptical, but the present disclosure is not limited thereto.

In FIGS. 9A and 9B, the upper holes UH1 and UH2 are disposed adjacent to the internal side surfaces IS1 and IS2 of the metal terminals 141b and 142b in the length direction, and the lower holes LH1 and LH2 are disposed adjacent to the external side surfaces OS1 and OS2 of the metal terminals 141b and 142b in the length direction, but the present disclosure is not limited thereto. For example, the positions of the upper holes UH1 and UH2, and the lower holes LH1 and LH2 may be swapped. In this case, the upper holes UH1 and UH2 may be disposed adjacent to the external side surfaces OS1 and OS2 of the metal terminals 141b and 142b in the length direction, and the lower holes LH1 and LH2 may be disposed adjacent to the internal side surfaces IS1 and IS2 of the metal terminals 141b and 142b in the length direction.

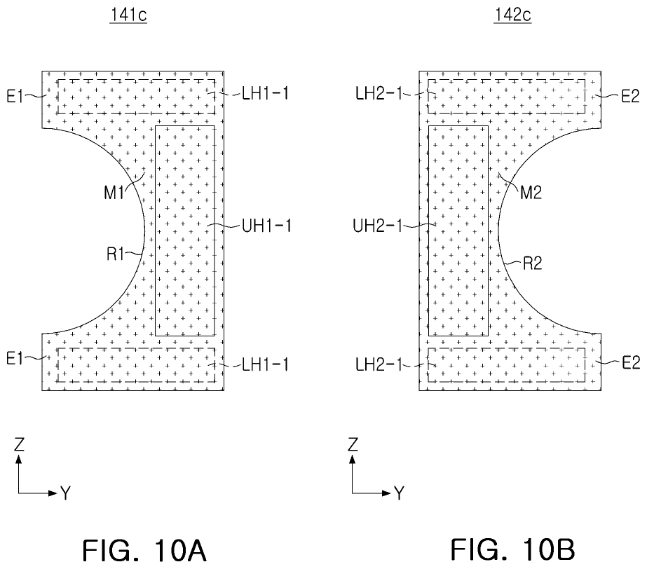

Referring to FIGS. 10A and 10B, the metal terminals 141c and 142c may include the main portions M1 and M2 facing the recess portions R1 and R2 in the length direction and the extension portions E1 and E2 disposed on both sides of the main portions M1 and M2 in the width direction. For example, the main portions M1 and M2 may refer to a region among the metal terminals 141c and 142c, whose length changes along the width direction, and the extension portions E1 and E2 may refer to a region among the metal terminals 141c and 142c, whose length does not change along the width direction. The length of the main portions M1 and M2 may, for example, become smaller as it approaches the central portions of the metal terminals 141c and 142c in the width direction. The cross section of the extension portions E1 and E2 may be, for example, rectangular in shape.

In an embodiment, the upper holes UH1-1 and UH2-1 may be disposed in the main portions M1 and M2, and the lower holes LH1-1 and LH2-1 may be disposed in the extension portions E1 and E2. The upper holes UH1-1 and UH2-1 may have a shape extended in the width direction, and the lower holes LH1-1 and LH2-1 may have a shape extended in the length direction. The upper holes UH1-1 and UH2-1 may have a shape in which the dimension in the width direction is greater than the dimension in the length direction, and the lower holes LH1-1 and LH2-1 may have a shape in which the dimension in the length direction is greater than the dimension in the width direction.

The upper holes UH1-1 and UH2-1 may be disposed, for example, across the entire of the main portions M1 and M2 in the width direction. The lower holes LH1-1 and LH2-1 may be respectively disposed in two extension portions E1 and E2 disposed on both sides of the main portions M1 and M2. The cross sections of the upper holes UH1-1 and UH2-1, and the lower holes LH1-1 and LH2-1 may have a square shape.

In an embodiment, when viewed in the thickness direction, the metal terminals 141c and 142c may have an area of a region where the upper holes UH1-1 and UH2-1, and the lower holes LH1-1 and LH2-1 are disposed, may be greater than an area of a region where the upper holes UH1-1 and UH2-1, and the lower holes LH1-1 and LH2-1 are not disposed.

FIGS. 10A and 10B illustrate a structure in which upper holes UH1-1 and UH2-1 are disposed in the main portions M1 and M2, and lower holes LH1-1 and LH2-1 are disposed in the extension portions E1 and E2, but the present disclosure is not limited thereto. The upper hole may be disposed in the extension portion and the lower hole may be disposed in the main portion. In this case, the upper hole may have a shape extending in the length direction, and the lower hole may have a shape extending in the width direction. That is, the shape and position of the upper portion and lower holes may be interchanged.

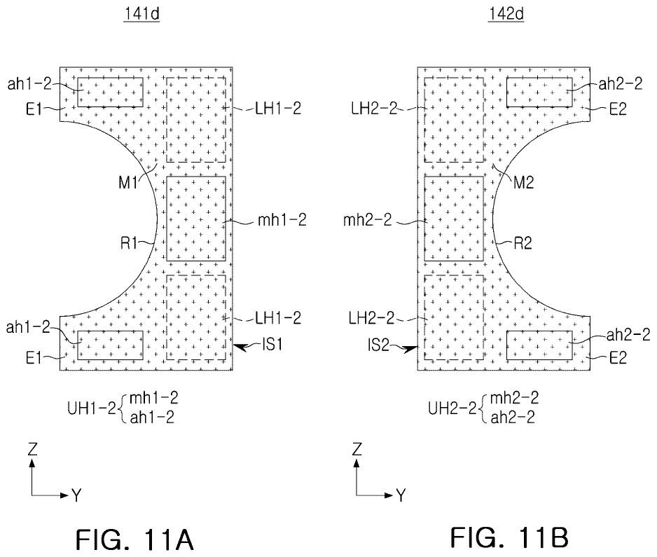

Referring to FIGS. 11A and 11B, the metal terminals 141d and 142d may include the main portions M1 and M2 facing the recess portions R1 and R2 in the length direction and the extension portions E1 and E2 disposed on both sides of the main portions M1 and M2 in the width direction.

In an embodiment, the upper holes UH1-2 and UH2-2 may include main upper holes mh1-2 and mh2-2 disposed in the main portions M1 and M2, and auxiliary upper holes ah1-2 and ah2-2 disposed in the extension portions E1 and E2.

A dimension of the main upper holes mh1-2 and mh2-2 in the width direction may be greater than a dimension of the auxiliary upper holes ah1-2 and ah2-2 in the width direction. The auxiliary upper holes ah1-2 and ah2-2 may be respectively disposed in the two extension portions E1 and E2 disposed on both sides of the main portions M1 and M2.

The lower holes LH1-2 and LH2-2 may be disposed on both sides of the main upper holes mh1-2 and mh2-2 in the width direction, but may be disposed closer to the internal side surfaces IS1 and IS2 of the metal terminals 141d and 142d in the length direction than the auxiliary upper holes ah1-2 and ah2-2. The lower holes LH1-2 and LH2-2 may be formed across the main portions M1 and M2, and the extension portions E1 and E2.

The cross-sections of the upper holes UH1-2 and UH2-2, and the lower holes LH1-2 and LH2-2, in the length-width directions may have a rectangular shape.

In an embodiment, when viewed in the thickness direction, the metal terminals 141d and 142d may have a region in which the upper holes UH1-2 and UH2-2, and the lower holes LH1-2 and LH2-2 are disposed, may be greater than a region in which the upper holes UH1-2 and UH2-2, and the lower holes LH1-2 and LH2-2 are not disposed.

Meanwhile, a shape and position of the upper holes UH1-2 and UH2-2, and the lower holes LH1-2 and LH2-2 may be interchanged. In this case, the lower hole may include the main lower hole disposed in the main portion and the auxiliary lower hole disposed in the extension portion, and the upper hole may be disposed on both sides of the main lower hole in the width direction, but may be disposed closer to the internal surface of the metal terminal in the length direction than the auxiliary lower hole.

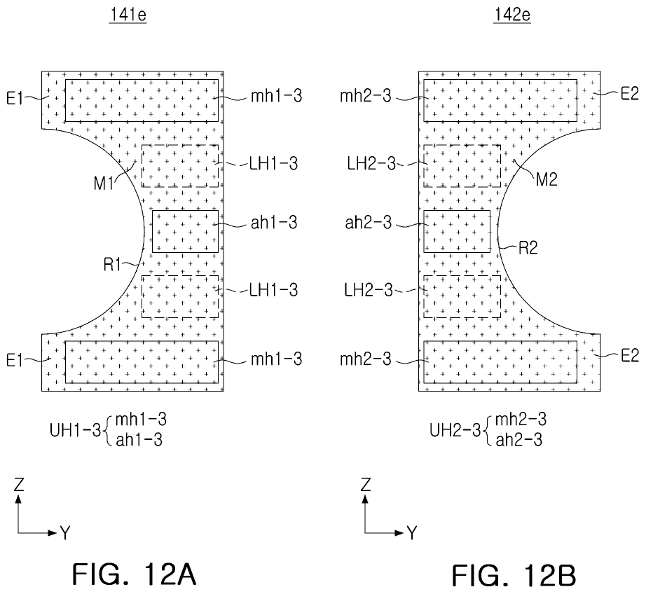

Referring to FIGS. 12A and 12B, the metal terminals 141e and 142e may include the main portions M1 and M2 facing the recess portions R1 and R2 in the length direction and the extension portions E1 and E2 disposed on both sides of the main portions M1 and M2 in the width direction.

In an embodiment, the upper holes UH1-3 and UH2-3 may include auxiliary upper holes ah1-3 and ah2-3 disposed in the main portions M1 and M2, and main upper holes mh1-3 and mh2-3 disposed in the extension portions E1 and E2. In an embodiment, the upper holes UH1-3 and UH2-3 may include auxiliary upper holes ah1-3 and ah2-3 disposed in the main portions M1 and M2, and main upper holes mh1-3 and mh2-3 disposed in the extension portions E1 and E2. The main upper holes mh1-3 and mh2-3 may be respectively disposed in two extension portions E1 and E2 disposed on both sides of the main portions M1 and M2.

The lower holes LH1-3 and LH2-3 may be disposed between the auxiliary upper holes ah1-3 and ah2-3, and the main upper holes mh1-3 and mh2-3 when viewed in the thickness direction. A dimension of the lower holes LH1-3 and LH2-3 in the length direction may be greater than a dimension of the auxiliary upper holes ah1-3 and ah2-3 in the length direction, and smaller than a dimension of the main upper holes mh1-3 and mh2-3 in the length direction.

The cross-sections of the upper holes UH1-3 and UH2-3, and the lower holes LH1-3 and LH2-3, in the length-width direction may have a rectangular shape.

Meanwhile, the shape and position of the upper holes UH1-3 and UH2-3, and the lower holes LH1-3 and LH2-3 may be interchanged. In this case, the lower hole may include an auxiliary lower hole disposed in the main portion and a main lower hole disposed in the extension portion, and the upper hole may be disposed between the auxiliary lower hole and the main lower hole when viewed in the thickness direction.

### Method of Manufacturing Multilayer Electronic Component

Hereinafter, an example of a method for forming a multilayer electronic component 100 will be described. The description is based on the multilayer electronic component 100 including metal terminals 141 and 142 illustrated in FIGS. 1 to 7, but the manufacturing method of the multilayer electronic component 100 is not limited thereto.

First, a ceramic powder for forming a dielectric layer 111 is prepared. The ceramic powder may be a perovskite compound powder represented by ABO₃. The ceramic powder may include at least one of, for example, BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃, and (Ca₁₋ₓSrₓ)(Zr_{1-y}Ti_{y})O₃ (0<x≤0.5, 0<y≤0.5). The BaTiO₃ powder may be synthesized, for example, by reacting a titanium raw material such as titanium dioxide with a barium raw material such as barium carbonate. Methods for synthesizing the ceramic powder include, for example, a solid-state method, a sol-gel method, a hydrothermal synthesis method, and the like, but the present disclosure is not limited thereto. Next, the prepared ceramic powder is dried and ground, and then mixed with an organic solvent such as ethanol and a binder such as polyvinyl butyral to prepare a ceramic slurry. The ceramic slurry is applied to a carrier film and dried to prepare a ceramic green sheet.

Next, a conductive paste for internal electrodes, including metal powder, a binder, an organic solvent and the like, is printed on the ceramic green sheet to a predetermined thickness using a screen-printing method, a gravure printing method or the like, thereby forming an internal electrode pattern.

Thereafter, the ceramic green sheet with the internal electrode pattern printed thereon is peeled from the carrier film, and then, a predetermined number of ceramic green sheets with the internal electrode pattern printed thereon are laminated and pressed together to form a ceramic laminate. A predetermined number of ceramic green sheets without the internal electrode pattern may be laminated on the upper and lower portions of the ceramic laminate to form cover portions 112 and 113 after firing. The ceramic laminate is then cut to a predetermined chip size, and the cut chips are fired to form the body 110. The firing may be performed, for example, in a 1.0% H₂/99.0% N₂ to 3.5% H₂/96.5% N₂ (H₂O/H₂/N₂ atmosphere), at a temperature of 1000° C. to 1400° C. for 1 to 3 hours.

Next, external electrodes 131 and 132 are formed. For example, when the base electrode layers 131a and 132a include a sintered electrode layer, the body 110 may be dipped in a conductive paste for external electrodes including metal powder, glass frit, a binder, and an organic solvent, and then the conductive paste for external electrodes may be sintered at a temperature of 500° C. to 900° C. to form a sintered electrode layer.

For example, when the base electrode layers 131a and 132a include a resin electrode layer, the body may be dipped in a conductive resin composition including metal powder, resin, binder, and organic solvent, and then cured and heat-treated at a temperature of 250° C. to 550° C. to form a resin electrode layer.

Additionally, the metal layers 131b and 132b, may be formed on the base electrode layers 131a and 132a by additionally performing an electrolytic plating method and/or an electroless plating method.

Next, after preparing the metal core MC in which the recess portions R1 and R2 are formed, a hole may be machined on the surface of the metal core MC using a method such as half etching. Through the holes processing, upper holes UH1 and UH2, and lower holes LH1 and LH2 may be formed. The metal terminals 141 and 142 may be formed by forming the plating layer PL on the surface of a machined metal core MC using an electrolytic plating method and/or an electroless plating method. The metal core MC may include, for example, one or more of Cu, Ni, Ag, Sn, Pt, Pd, Fe, Al, and alloys thereof, phosphor bronze, and stainless steel, and the plating layer PL may include, for example, one or more of Ni, Sn, and Au.

Next, the multilayer electronic component 100 may be formed by attaching a metal terminals 141 and 142 to the external electrodes 131 and 132 using a conductive adhesive.

### Experimental Example

After preparing a multilayer ceramic capacitor of size 1608 (length: approximately 1.6 mm, width: approximately 0.8 mm, thickness: approximately 0.8 mm), a sample chip was prepared by attaching the metal terminal to the external electrode.

In the comparative example, only a recess portion was formed in the metal terminal, and the upper hole and lower hole were not formed.

In Example 1, upper portion and lower holes were formed in the metal terminal, respectively, and the metal terminal had the shape illustrated in FIGS. 7A and 7B.

In Example 2, upper portion and lower holes were formed in the metal terminal, respectively, and the metal terminal had the shape illustrated in FIGS. 8A and 8B.

Comparative examples, sample chips of Examples 1 and 2 were mounted on the printed circuit board using the conductive mounting agent, and then the respective bonding strength and bending strength were measured.

An adhesion strength test is defined as a force applied to the printed circuit board at the moment when the sample chip is fractured when the opposite surface of the printed circuit board on which a sample chip is mounted is pressed until the sample chip is fractured, and an average value of the adhesion strength of 40 sample chips each in Comparative Example, Example 1, and Example 2 was measured.

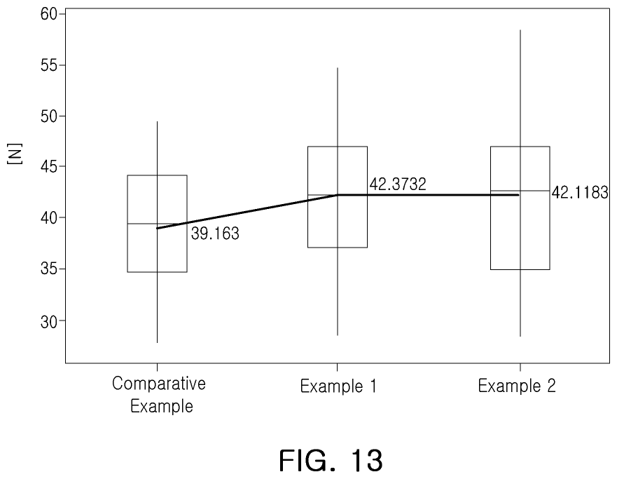

FIG. 13 is a graph illustrating the bonding strength of comparative examples, examples 1 and 2. Referring to FIG. 13, the average value of the bonding strength of the comparative example was 39.163 N, the average value of the bonding strength of Example 1 was 42.3732 N, and the average value of the bonding strength of Example 2 was 42.1183 N. That is, it may be confirmed that Examples 1 and 2 have superior bonding strength compared to the comparative example.

The bending strength test was conducted by pressing the surface opposite to the mounting surface of the printed circuit board on which the sample chip was mounted by approximately 2 mm for 10 seconds, and then a voltage of 1 Vr was applied for 24 hours at a temperature of 85° C. and a relative humidity of 85%. Afterwards, the cross-section of the sample chip was observed under a microscope, and the number of sample chips in which bending cracks occurred was recorded in Table 1 below.

TABLE 1

| | Bending |
|---|---|
| Division | Cracks |
| Comparative | 10 |
| example | |
| Example 1 | 4 |
| Example 2 | 9 |

Referring to Table 1 above, Examples 1 and 2 had less occurrence of bending cracks compared to the comparative example. In particular, Example 1 had a lower rate of bending crack occurrence than Example 2, and this is believed to be because bending cracks mainly occurred at the end of the band portion, and Example 1 effectively reduced the rigidity of the metal terminal and absorbed stress by disposing the upper hole adjacent thereto.

### 2. Second Example

### Multilayer Electronic Components

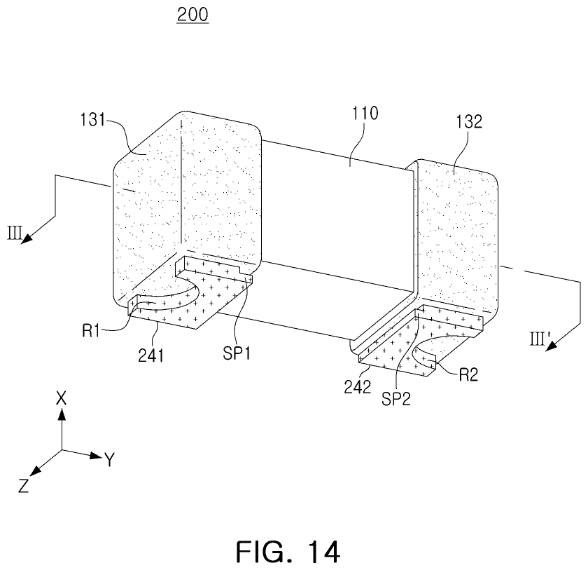

FIG. 14 is a perspective view schematically illustrating a multilayer electronic component according to another embodiment of the present disclosure.

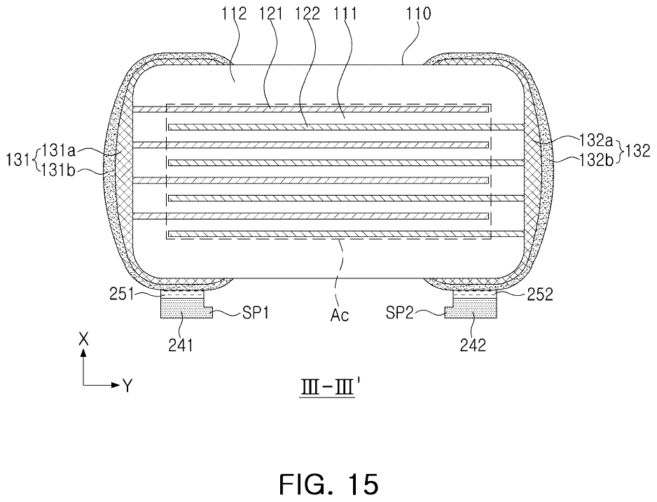

FIG. 15 is a schematic cross-sectional view taken along line III-III′ cross-section of FIG. 14.

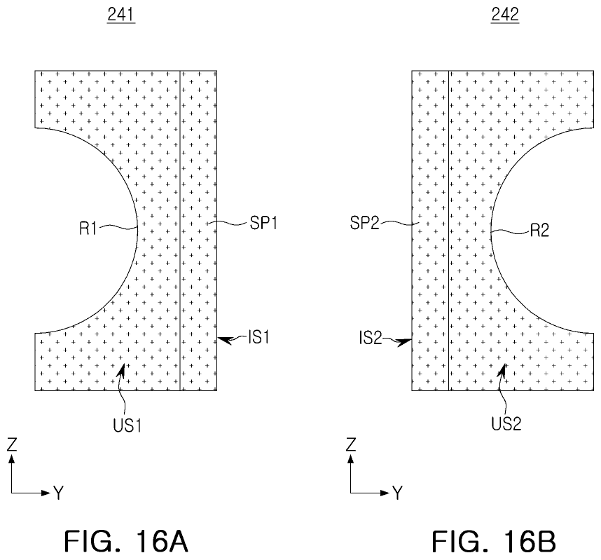

FIGS. 16A and 16B are plan views of a first metal terminal and a second metal terminal of FIG. 14.

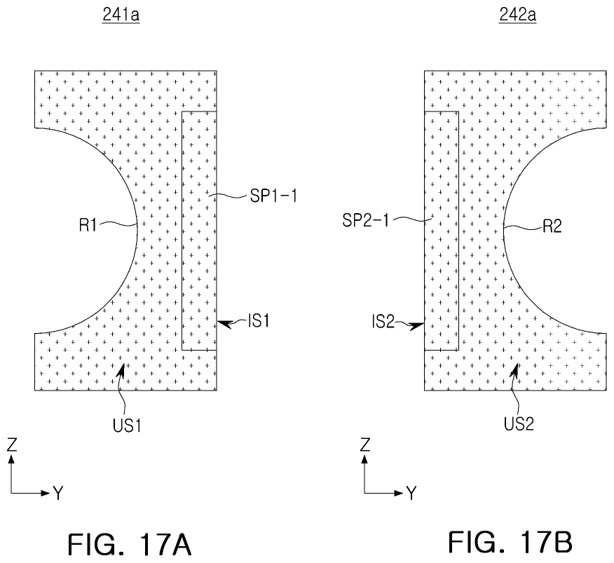

FIGS. 17A, 17B, 18A, 18B, 19A and 19B are plan views of a first metal terminal and a second metal terminal of other embodiments of the present disclosure, corresponding to FIG. 16.

Hereinafter, a multilayer electronic component 200 according to another embodiment of the present disclosure will be described with reference to FIGS. 14A to 19B. For configurations identical/similar to the configuration of the multilayer electronic component 100 described in FIGS. 1 to 12, identical/similar reference numerals are used, and duplicate descriptions are omitted.

The laminated electronic component 200 may include the body 110, external electrodes 131 and 132, and metal terminals 241 and 242.

Recessed portions R1 and R2 may be disposed in the metal terminals 241 and 242. The first recessed portion R1 may be disposed in a first metal terminal 241, and the second recessed portion R2 may be disposed in a second metal terminal 242.

The recessed portions R1 and R2 may have a concave shape toward the internal side surfaces IS1 and IS2 of the metal terminals 241 and 242 in the length direction. However, the present disclosure is not limited thereto, and the cross-sections (L-W cross sections) of the recessed portions R1 and R2 in the length and width directions may have a square shape.

When the multilayer electronic component 200 is mounted on a printed circuit board using a conductive mounting agent, the recessed portions R1 and R2 may serve as solder pockets by providing a space in which the molten conductive mounting agent can be filled. In this way, a height of the solder fillet rising in the thickness direction along the external electrodes 131 and 132 may be lowered, thereby blocking the transmission path of the piezoelectric vibration generated in the body 110, thereby reducing the acoustic noise of the multilayer electronic component 200.

In an embodiment, the metal terminals 241 and 242 may include step portions SP1 and SP2 having a relatively thin thickness. The first metal terminal 241 may include a first step portion SP1 having a relatively thin thickness, and the second metal terminal 242 may include a second step portion SP2 having a relatively thin thickness.

That is, the metal terminals 241 and 242 may have step portions SP1 and SP2 defined on the upper surfaces US1 and US2, and the internal side surfaces IS1 and IS2 in the length direction. Here, the upper surfaces US1 and US2 of the metal terminals 241 and 242 may mean the uppermost surface of the metal terminals 241 and 242.

The rigidity of the metal terminals 241 and 242 may be reduced through the step portions SP1 and SP2, thereby improving the bending strength of the multilayer electronic component 200. In particular, the step portions SP1 and SP2 may be disposed on the upper surfaces US1 and US2, and the internal side surfaces IS1 and IS2 of the metal terminals 241 and 242 in the length direction adjacent to the ends of the external electrodes 131 and 132. Since the ends of the external electrodes 131 and 132 are the points where the occurrence of bending cracks mainly begins, the bending strength of the multilayer electronic component 200 may be effectively improved by forming the step portions SP1 and SP2 in that region.

Referring to FIGS. 16A and 16B, the step portions SP1 and SP2 may have a shape extending in the width direction. Specifically, the step portions SP1 and SP2 may be formed across the entire width direction of the metal terminals 241 and 242.

Hereinafter, various modified examples of the metal terminal will be described with reference to FIGS. 17aA to 19B. Each variation is described separately, but overlapping explanations are omitted.

Referring to FIGS. 17A and 17B, the metal terminals 241a and 242a may include the step portions SP1-1 and SP2-1 having a relatively thin thickness. The metal terminals 241a and 242a may have step portions SP1-1 and SP2-1 defined on the upper surfaces US1 and US2, and the internal side surfaces IS1 and IS2 in the length direction.

The step portions SP1-1 and SP2-1 may have a shape extending in the width direction. However, the step portions SP1-1 and SP2-1 may be formed over a portion of the width direction of the metal terminals 241a and 242a. For example, the step portions SP1-1 and SP2-1 may be spaced apart from both surfaces of the metal terminals 241a and 242a in the width direction. For example, a dimension of the step portions SP1-1 and SP2-1 in the width direction may be smaller than a dimension of the metal terminals 241a and 242a in the width direction.

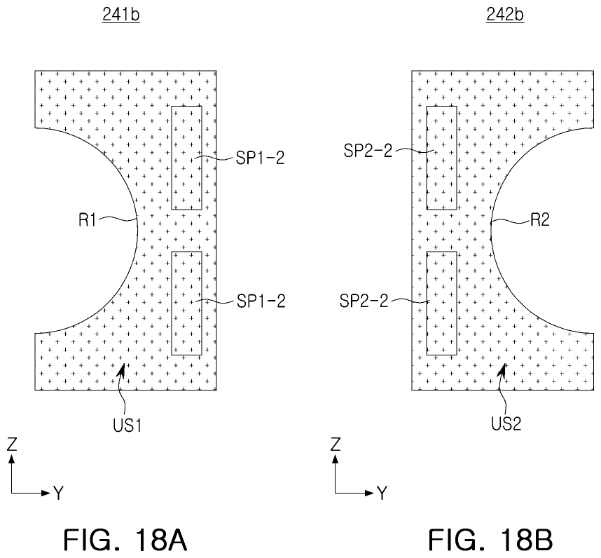

Referring to FIGS. 18A and 18B, the metal terminals 241b and 242b may include the step portions SP1-2 and SP2-2 having a relatively thin thickness. Metal terminals 241b and 242b may have step portions SP1-2 and SP2-2 defined on the upper surfaces US1 and US2.

The step portions SP1-2 and SP2-2 may have a shape extending in the width direction. However, the step portions SP1-2 and SP2-2 may be formed over a portion of the width direction of the metal terminals 241b and 242b. For example, the step portions SP1-2 and SP2-2 may be spaced apart from both surfaces of the metal terminals 241b and 242b in the width direction. For example, a dimension of the step portions SP1-2 and SP2-2 in the width direction may be smaller than a dimension of the metal terminals 241b and 242b in the width direction.

The step portions SP1-2 and SP2-2 may be disposed in multiple. For example, a plurality of first step portions SP1-2 may be disposed on a first metal terminal 241b, and a plurality of second step portions SP2-2 may be disposed on a second metal terminal 242b. A plurality of first step portions SP1-2 may be spaced apart in the width direction, and a plurality of second step portions SP2-2 may be spaced apart in the width direction, respectively. A plurality of step portions SP1-2 and SP2-2 may be spaced apart from the internal surface of the metal terminals 241b and 242b in the length direction. However, the present disclosure is not limited thereto, and a plurality of step portions SP1-2 and SP2-2 may be opened to the internal surface of the metal terminals 241b and 242b in the length direction.

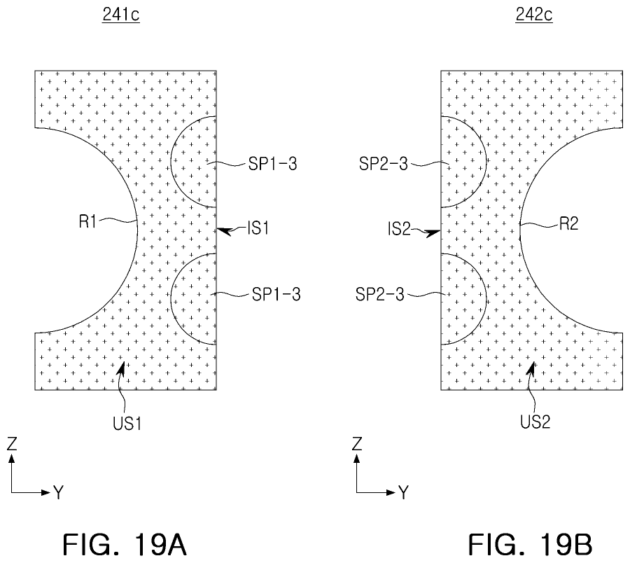

Referring to FIGS. 19A and 19B, the metal terminals 241c and 242c may include step portions SP1-3 and SP2-3 having a relatively thin thickness. The metal terminals 241c and 242c may have step portions SP1-3 and SP2-3 defined on the upper surfaces US1 and US2 and the internal side surfaces IS1 and IS2 in the length direction.

The step portions SP1-3 and SP2-3 may have an arc shape when viewed in the thickness direction. The step portions SP1-3 and SP2-3 may be formed across a portion of the width direction of the metal terminals 241c and 242c. For example, the step portions SP1-3 and SP2-3 may be spaced apart from both surfaces of the metal terminals 241c and 242c in the width direction. For example, a dimension of the step portions SP1-3 and SP2-3 in the width direction may be smaller than a dimension of the metal terminals 241c and 242c in the width direction.

The step sections SP1-3 and SP2-3 may be disposed in multiple. For example, a plurality of first step portions SP1-3 may be disposed on a first metal terminal 241c, and a plurality of second step portions SP2-3 may be disposed on a second metal terminal 242c. A plurality of first step portions SP1-3 may be spaced apart in the width direction, and a plurality of second step portions SP2-3 can be spaced apart in the width direction, respectively. A plurality of step portions SP1-3 and SP2-3 may be opened to the internal side surfaces IS1 and IS2 of the metal terminals 241c and 242c in the length direction. However, the present disclosure is not limited thereto, and a plurality of step portions SP1-3 and SP2-3 may be spaced apart from the internal surface of the metal terminals 241c and 242c in the length direction.

The present disclosure is not limited by the above-described embodiments and accompanying drawings, but is intended to be limited by the appended claims. Therefore, various forms of substitution, modification and change will be possible by those skilled in the art within the scope of the technical spirit of the present disclosure described in the claims, and this will also be said to fall within the scope of the present disclosure.

In addition, the expression ‘an embodiment’ does not indicate the same embodiment, and is provided to emphasize and describe different unique characteristics. However, the embodiments presented above are not excluded from being implemented in combination with features of another embodiment. For example, even if a matter described in one specific embodiment is not described in another embodiment, it may be understood as a description related to another embodiment, unless there is a description to the contrary or contradicting the matter in another embodiment.

In the present disclosure, the term “connected” includes not only direct connection but also indirect connection through an adhesive layer or the like. Furthermore, the term “electrically connected” includes both physically connected and unconnected cases. In addition, expressions such as first and second are used to distinguish one component from another, and do not limit the order and/or importance of the components. In some cases, without departing from the scope of rights, a first element may be named a second element, and similarly, a second element may be named a first element.

While example embodiments have been illustrated and described above, it will be apparent to those skilled in the art that modifications and variations could be made without departing from the scope of the present disclosure as defined by the appended claims.

What is claimed is:

1. A multilayer electronic component comprising:
a body including a dielectric layer and an internal electrode disposed alternately with the dielectric layer, the body having first and second surfaces opposing each other in a thickness direction, third and fourth surfaces connected to the first and second surfaces and opposing each other in a length direction, and fifth and sixth surfaces connected to the first to fourth surfaces and opposing each other in a width direction;
an external electrode disposed on the third or fourth surface and extending to a portion of the first and second surfaces; and
a metal terminal disposed on the first or second surface and connected to the external electrode,
wherein a recess portion is disposed on an external side surface of the metal terminal in the width direction,
wherein an upper hole and a lower hole are disposed on upper and lower surfaces of the metal terminal, respectively, in the thickness direction, and
wherein the upper hole does not overlap the lower hole along the thickness direction.

2. The multilayer electronic component of claim 1, wherein each of the upper hole and the lower hole is formed in plural, and
wherein a plurality of upper holes do not overlap a plurality of lower holes along the thickness direction.

3. The multilayer electronic component of claim 1, wherein each of the upper hole and the lower hole is formed in plural,
wherein a plurality of upper holes are disposed closer to an internal side surface of the metal terminal in the length direction than a plurality of lower holes, and
wherein the plurality of upper holes are disposed closer to a center portion of the metal terminal in the width direction than the plurality of lower holes.

4. The multilayer electronic component of claim 1, wherein each of the upper hole and the lower hole is disposed in plural,
wherein a plurality of lower holes are disposed closer to an internal side surface of the metal terminal in the length direction than a plurality of upper holes, and
wherein the plurality of lower holes are disposed closer to a center portion of the metal terminal in the width direction than the plurality of upper holes.

5. The multilayer electronic component of claim 3, wherein the plurality of upper holes are spaced apart from each other in the width direction, and
wherein the plurality of lower holes are spaced apart from each other in the width direction.

6. The multilayer electronic component of claim 4, wherein the plurality of upper holes are spaced apart from each other in the width direction, and
wherein the plurality of lower holes are spaced apart from each other in the width direction.

7. The multilayer electronic component of claim 1, wherein the recess portion has a concave shape toward an internal side surface of the metal terminal in the length direction.

8. The multilayer electronic component of claim 7, wherein the upper and lower holes are disposed alternately along a periphery of the recess portion when viewed in the thickness direction.

9. The multilayer electronic component of claim 1, wherein the metal terminal includes a main portion facing the recess portion in the length direction and an extension portion disposed on both sides of the main portion in the width direction,
wherein the upper hole is disposed in the main portion and extends in the width direction, and
wherein the lower hole is disposed in the extension portion and extends in the length direction.

10. The multilayer electronic component of claim 1, wherein the metal terminal includes a main portion facing the recess portion in the length direction and an extension portion disposed on both sides of the main portion in the width direction,
wherein the upper hole includes a main upper hole disposed in the main portion and an auxiliary upper hole disposed in the extension portion, and
wherein the lower hole is disposed on both sides of the main upper hole in the width direction, and the lower hole is disposed closer to an internal side surface of the metal terminal in the length direction than the auxiliary upper hole.

11. The multilayer electronic component of claim 1, wherein the metal terminal includes a main portion facing the recess portion in the length direction and an extension portion disposed on both sides of the main portion in the width direction,
wherein the upper hole includes an auxiliary upper hole disposed in the main portion and a main upper hole disposed in the extension portion, and
wherein the lower hole is disposed between the auxiliary upper hole and the main upper hole when viewed in the thickness direction.

12. The multilayer electronic component of claim 1, wherein a conductive adhesive is disposed between the external electrode and the metal terminal, and
wherein the conductive adhesive fills at least a portion of the upper hole.

13. The multilayer electronic component of claim 1, wherein the metal terminal includes a metal core and a plating layer disposed on the metal core, and
wherein the plating layer extends into internals of the upper hole and the lower hole.

14. The multilayer electronic component of claim 1, wherein the metal terminal has a step portion recessed from the upper surface of the metal terminal, the step portion having a smaller thickness than other portions of the metal terminal.

15. The multilayer electronic component of claim 14, wherein the step portion extends to a side surface of the metal terminal in the width direction.

16. The multilayer electronic component of claim 14, wherein the step portion is spaced apart from a side surface of the metal terminal in the width direction.

17. The multilayer electronic component of claim 14, wherein the step portion extends to an internal side surface of the metal terminal in the length direction.

18. The multilayer electronic component of claim 14, wherein the step portion is spaced apart from an internal side surface of the metal terminal in the length direction.

19. The multilayer electronic component of claim 14, wherein the step portion is formed in plural, and a plurality of step portions are spaced apart from each other.

20. A mounting board, comprising:
a printed circuit board including an electrode pad;
the multilayer electronic component according to claim 1 disposed on the printed circuit board; and
a conductive material disposed between the electrode pad and the metal terminal,
wherein the conductive material fills at least a portion of the lower hole.
